(19) United States
(12) Patent Application Publication
(10) Pub. No.: US 2008/0029020 A1
(43) Pub. Date: Feb. 7, 2008

(54) METHOD AND APPARATUS FOR PRODUCING GRANULAR CRYSTAL

(75) Inventors: Shin SUGAWARA, Shiga (JP); Eigo TAKAHASHI, Shiga (JP); Hisao ARIMUNE, Shiga (JP)

Correspondence Address: VOLPE AND KOENIG, P.C., UNITED PLAZA, SUITE 1600, 30 SOUTH 17TH STREET, PHILADELPHIA, PA, 19103, US

(73) Assignee: KYOCERA CORPORATION, Kyoto (JP)

(21) Appl. No.: 11/828,488

(22) Filed: Jul. 26, 2007

(30) Foreign Application Priority Data
Jul. 28, 2006 (JP) 2006-205577

(51) Int. Cl. C30B 30/06

(52) U.S. Cl. 117/73; 117/206

(57) ABSTRACT

A method for producing a granular crystal includes steps of melting a crystal to be a molten solution, ejecting a droplet of the molten solution from a nozzle with a three dimensional motion. An apparatus for producing a granular crystal includes a crucible, an actuator, and at least one nozzle. The crucible contains a molten solution of a crystal. The actuator moves at least one nozzle with three-dimensional motion. At least one nozzle ejects a droplet of the molten solution with a three dimensional motion.

### CROSS-REFERENCE TO RELATED APPLICATIONS

The present application claims priority under 35 U.S.C. §119 to Japanese Patent Application No. 2006-205577, filed Jul. 28, 2006. The contents of the application are incorporated herein by reference in its entirety.

### BACKGROUND OF THE INVENTION

1. Field of the Invention

The present invention relates to a method and an apparatus for producing a granular crystal suitable for a granular silicon crystal used for a photovoltaic converting device.

2. Description of the Related Art

Solar batteries including crystalline silicon wafers and having high conversion efficiency have been used practically. Crystalline silicon wafers are produced by slicing large monocrystalline silicon ingots having high crystallinity, low impurity concentrations, and uniform impurity distribution.

A long time is required to produce a large monocrystalline silicon ingot, causing low productivity and high production costs. Thus, developments of next-generation high-efficiency solar batteries that do not require such large monocrystalline silicon ingots have been strongly demanded.

As an example of promising photovoltaic converting devices in future markets, solar batteries including granular silicon crystals constituting photovoltaic converters have been receiving attention.

Fine silicon particles formed by pulverizing monocrystalline silicon materials or high-pure silicon particles obtained by gas-phase synthesis using a fluid-bed method are used as materials for forming granular silicon crystals. To form the material particles into globular shapes, there have been a method in which after the material particles are screened on the basis of size and weight, the screened material particles are melted in a vessel with infrared rays or a high-frequency coil and allowed to free-fall; and a method in which the material particles are melted by radio-frequency plasma heating.

However, these methods have disadvantages of difficulty in the uniformization of weight of the molten material particles, low productivity, and difficulty in forming uniform crystal grains.

Thus, as described in Japanese Unexamined Patent Application Publication No. 2002-292265, attempts have been made to form crystalline particles having a uniform particle size by the application of vibration along direction perpendicular to the axial direction of a nozzle and/or the axial direction. For example, reciprocating motion caused by driving a diaphragm with a motor applies linear reciprocating motion to a molten material, thereby improving particle size distribution.

However, when vibration is simply applied, molten material particles and/or crystalline particles that are falling freely may collide with each other to coalesce, resulting in a tendency to cause broad particle size distribution. Therefore, there is still room for the improvement of particle size distribution.

### SUMMARY OF THE INVENTION

According to one aspect of the present invention, the method for producing a granular crystal includes steps of melting a crystal to be a molten solution, ejecting a droplet of the molten solution from a nozzle with a three dimensional motion.

According to another aspect of the present invention, the method for producing a granular crystal includes a melting step, an ejecting step, and a solidifying step. In the melting step, a material is melted. In the ejecting step, a plurality of droplet of the molten material is ejected to disperse the plurality of droplet in a helical line. In the solidifying step, the droplets are solidified during dropping.

According to a further aspect of the present invention, an apparatus for producing a granular crystal includes a crucible, an actuator, and at least one nozzle. The crucible contains a molten solution of a crystal. The actuator moves at least one nozzle with three-dimensional motion. At least one nozzle ejects a droplet of the molten solution with a three dimensional motion.

### BRIEF DESCRIPTION OF THE DRAWINGS

A more complete appreciation of the invention and many of the attendant advantages thereof will be readily obtained as the same becomes better understood by reference to the following detailed description when considered in connection with the accompanying drawings, wherein:

FIG. 1 is a schematic side view of an apparatus for producing a granular crystal according to an embodiment of the present invention;

FIG. 2A is a schematic view illustrating a state in which a molten solution ejected from a nozzle is separated into a plurality of droplets according to an embodiment of the present invention;

FIG. 2B is a schematic view illustrating a state in which a molten solution ejected from a nozzle is separated into a plurality of droplets according to a method of the known art for producing a granular crystal;

FIG. 3A is a graph showing the grain size distribution of crystal grains obtained in a comparative example;

FIG. 3B is a graph showing the grain size distribution of crystal grains obtained in an example; and

FIG. 4 is a schematic side view of a structure of an apparatus for producing a granular crystal according to another embodiment of the present invention.

### DESCRIPTION OF THE PREFERRED EMBODIMENTS

The embodiments of this invention will be described with reference to the accompanying drawings, wherein like reference numerals designate corresponding or identical elements throughout the various drawings.

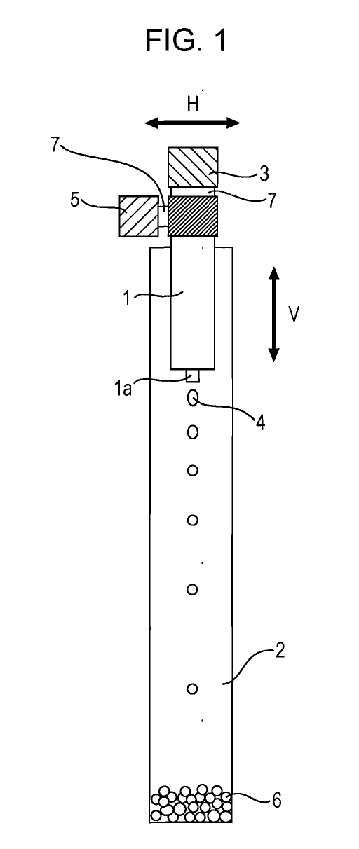

FIG. 1 is a schematic side view of an apparatus for producing a granular crystal according to an embodiment of the present invention. The apparatus for producing a granular crystal includes a crucible 1, a nozzle 1a, and an actuator. The actuator includes a longitudinally vibrating unit 3 and a laterally vibrating unit 5 and can move the nozzle 1a with three-dimensional motion. The crucible 1 is provided with the nozzle 1a. A molten solution of a crystal is ejected from the nozzle 1a in the form of a droplet 4. The droplet 4 is cooled in a drop tube 2 disposed in the cooling portion and/or cooled with a gas in the drop tube 2 to form a granular crystal.

A method according to an embodiment of the present invention for producing a granular crystal will be described with reference to FIG. 1.

The method according to an embodiment of the present invention for producing a granular crystal includes a step 1 of melting a crystal to be a molten solution; a step 2 of causing the nozzle 1a attached to the crucible 1 to undergo three-dimensional motion; a step 3 of ejecting the droplet 4 of the molten solution from the nozzle 1a with a three dimensional motion; a step 4 of dropping the droplet 4; and a step 5 of solidifying the droplet 4 during dropping.

In the step 1, the powdery the crystal is fed to the crucible 1 with a hopper disposed above the crucible 1. The hopper feeds the the crystal to the crucible 1 at regular time intervals in order to prevent a reduction in the amount of the molten solution by ejecting the molten solution of the material of the crystal from the crucible 1.

The material of the crystal in the crucible 1 is melted with an electromagnetic induction heating unit or a resistance heating unit disposed around the crucible 1. The electromagnetic induction heating unit is preferably used because it is not in direct contact with the crucible 1. In this way, the material is melted.

In the step 2, the nozzle 1a attached to an end (bottom end) of the crucible 1 undergoes three-dimensional motion from immediately before the molten solution is ejected from the nozzle 1a in the form of the droplet 4. The three-dimensional motion of the nozzle 1a is, for example, compound motion that is a combination of longitudinal motion in which the nozzle 1a is reciprocally moved (one-dimensional motion) along the direction of gravity and two-dimensional motion on a lateral plane perpendicular to the direction of the longitudinal motion.

The molten material is ejected from the nozzle in the form of a column (hereinafter, referred to as a “liquid column”). The liquid column can be fragmented into a plurality of droplets by applying the liquid column longitudinal vibration.

The longitudinal motion is applied to the nozzle 1a (and crucible 1) in such a manner that the molten solution effected from the nozzle 1a in the form of the liquid column is easily fragmented into the plurality of droplets. Thus, the frequency of the longitudinal motion is preferably about 1 kHz to 50 kHz. When the frequency of the longitudinal motion is about 1 kHz to 50 kHz, productivity and uniformity in the grain size of the granular crystals 6 are liable to increase.

The amplitude of the longitudinal motion is preferably about 0.2 to 50 μm. When the amplitude of the longitudinal motion is about 0.2 to 50 μm, uniformity in the grain size of the granular crystals 6 are liable to increase.

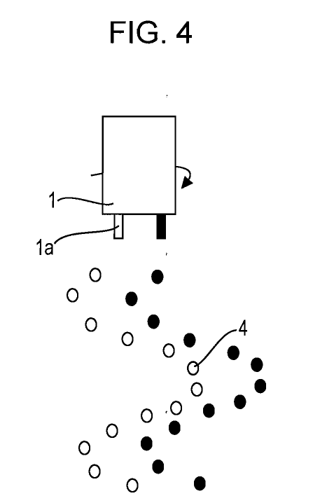

The two-dimensional motion in the lateral direction can move the plurality of droplet in such a manner that distances between the plurality of droplet increase. For example, the droplets are helically dropped to be dropped away from the extension of the axis of the nozzle 1a (see FIG. 4).

That is, the method according to the present invention for producing the granular crystal probably has the following effects: In the longitudinal motion, the fall velocity of the droplet 4 ejected when the nozzle 1a moves downward is higher than that of the droplet 4 ejected when the nozzle 1a moves upward. Thus, in the case of the longitudinal motion alone, the difference in fall velocity results in a phenomenon in which a droplet 4 comes into contact with another droplet 4 to coalesce. Therefore, the longitudinal motion is combined with two-dimensional motion in a lateral direction. This prevents coalescence because even when a droplet 4 catches up with another droplet 4 during dropping, they are laterally spaced.

In the case where the lateral motion is motion, such as simple harmonic oscillation, having a stop point, the plurality of droplets ejected at the stop point coalesce easily due to no lateral space between the droplets 4. Thus, the lateral motion is preferably two-dimensional motion that does not have a stop point, e.g., circular motion or elliptic motion, (the velocity of the motion is not zero at any given time). In this case, all of the droplets 4 are laterally spaced; hence, coalescence does not occur.

For example, when the two-dimensional motion in the lateral direction is circular motion or elliptic motion, many droplets 4 ejected from the nozzle 1a are helically dispersed in a space in the initial stage of dropping. Each of the droplets 4 undergoes parabolic motion so as to be dropped away from the center axis of the drop tube 2. Loci of the parabolic motion do not overlap one another. The lateral distance between the loci increases with dropping. Thus, many droplets 4 ejected from the nozzle 1a do not coalesce.

The longitudinal motion need not be complete reciprocating motion but may be vertically long elliptic motion.

The two-dimensional motion in a lateral plane is motion in which the speed of the nozzle 1a that undergoes circular motion or elliptic motion is not zero at any given time when the lateral plane is viewed in plan. In this case, when the molten solution ejected from the nozzle 1a in the form of a liquid column is fragmented into the plurality of droplets 4, the droplets 4 are laterally spaced, thus preventing the coalescence of the droplets 4. Therefore, many granular crystals 6 having a substantially uniform grain size can be produced.

In the case where the two-dimensional motion on the lateral plane is circular motion, the frequency of the circular motion is preferably about 1/100 to ½ of the frequency of the longitudinal motion. When the frequency of the circular motion is about 1/100 to ½ of the frequency of the longitudinal motion, the diameter of the locus of the circular motion decreases in order to reduce nonuniformity in the grain size of the granular crystals 6, and the separation effect of separating the granular crystals 6 tends to increase.

The amplitude (the diameter of the locus) of the circular motion is preferably about 10 μm to 10 mm. When the amplitude (the diameter of the locus) of the circular motion is about 10 μm to 10 mm, the separation effect of separating the granular crystals 6 tends to increase, and it results in ease in controlling the crucible 1 by the laterally vibrating unit 5, easily causing motion with noise.

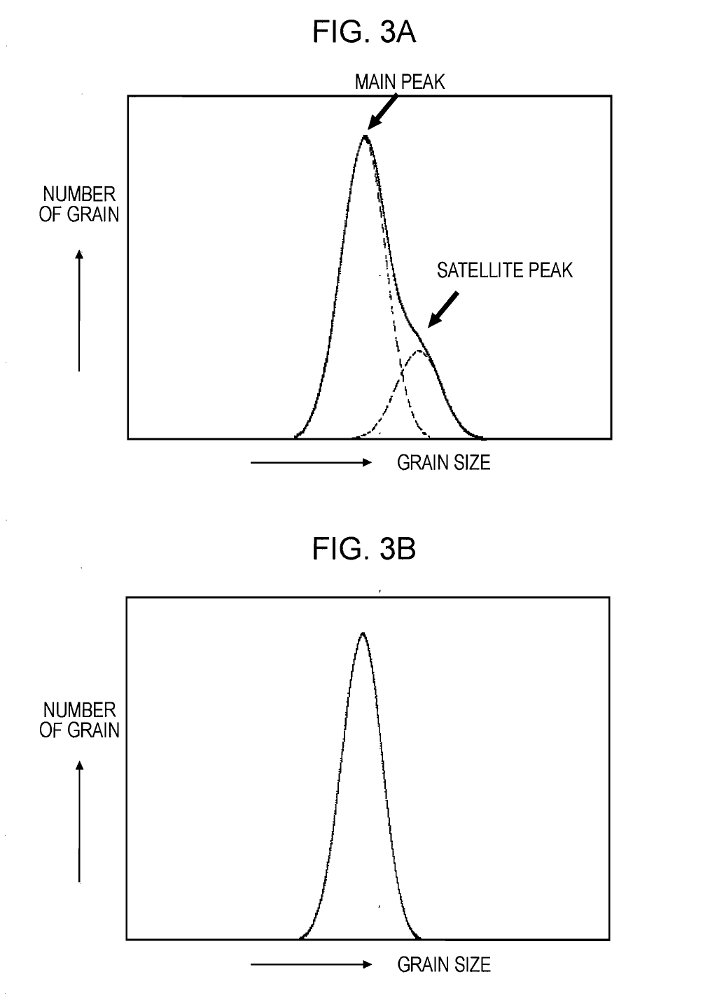

The two-dimensional motion on the lateral plane preferably has a frequency substantially equal to the natural frequency of the crucible 1. In this case, experiments by the inventors demonstrated that grain size distribution of the granular crystals was narrower than that shown in FIG. 3B. Detailed mechanism of action is not clear. It is speculated that the absorption of vibration to the molten solution of the material of the crystal in the crucible 1 suppresses the occurrence of large self-excited vibration of the crucible 1 at the natural frequency and prevents the superposition of vibration to be noise on the two-dimensional motion in the lateral direction. Thus, allowing the frequency of the two-dimensional motion on the lateral plane to conform to the natural frequency of the crucible 1 prevents the occurrence of large self-excited vibration of the crucible 1 and eliminates the superposition of vibration to be noise; hence, the crucible 1 undergoes motion having a clear locus. Therefore, the granular crystals 6 have a more uniform grain size.

The natural frequency of the crucible 1 depends on the material, size, weight, and the like of the crucible 1. For example, when the natural frequency F of the crucible 1 in the lateral direction is about 100 Hz, the frequency of the two-dimensional motion on the lateral plane is preferably F±10% (F±10 Hz).

The three-dimensional motion of the nozzle 1a may include the longitudinal motion and the two-dimensional motion on the lateral plane and may include another motion.

In the step 3, when the molten solution is ejected from the nozzle 1a in the form of the droplets 4, the droplets 4 can be efficiently ejected by increasing the pressure of an atmospheric gas, such as an argon gas, in the crucible 1 compared with atmospheric pressure and pressurizing the surface of the molten solution. This results in a number of droplets 4 ejected from the nozzle 1a of about 10,000/sec. The droplets 4 ejected from the nozzle 1a preferably have a diameter of about 50 to 700 μm. When the droplets 4 ejected from the nozzle 1a have a diameter of about 50 to 700 μm, uniformity in the grain size of the granular crystals 6 tends to increase.

The hole of the nozzle 1a has a diameter of about 40 to 300 μm.

In the step 4, when the droplets 4 are dropped, the droplets 4 are dropped through the drop tube 2 attached to the nozzle 1a of the crucible 1, the drop tube 2 extending downward. The drop tube 2 is composed of a material, such as silicon carbide, having a melting point higher than that of the droplet 4 composed of silicon or the like. The drop tube 2 preferably has a inner diameter such that the droplets 4 does not easily come into contact with the drop tube 2 and preferably has an inner diameter of about 1 to 5 m. When the drop tube 2 has an inner diameter of about 1 to 5 m, the probability of non-contact between the droplet 4 and the inner surface of the drop tube increase, and the size of the apparatus is reduced.

The atmospheric gas in the drop tube 2 is an inert gas, such as an argon gas, in order to prevent contamination from the atmospheric gas to the droplets 4.

In the step 5, the droplets 4 can be solidified during dropping. To solidify the droplets 4 during dropping, the drop tube 2 has a sufficient length required for the solidification of the droplets 4 during dropping. Thus, the drop tube 2 preferably has a length of about 4 to 50 m. When the drop tube 2 has a length of about 4 to 50 m, it results in ease in solidifying the droplets 4 during dropping, and the size of the drop tube 2 is reduced.

The drop tube 2 may be absent. In this case, the droplets 4 are dropped in air. When the droplets 4 are dropped in air, the droplets 4 absorb foreign matter in air, thereby facilitating degradation in the quality and purity of the crystals.

The crucible 1 is a vessel for containing the molten solution of the material of the crystal desired. The nozzle 1a is disposed at the bottom of the crucible 1. The droplets 4 are ejected from the nozzle 1a. The droplets 4 are dropped through the drop tube 2. The hopper (not shown) is disposed above the crucible 1, stores a powdery of the crystal, and feeds the material of the crystal to the crucible 1 at regular time intervals. The atmospheric gas in the crucible 1 is an inert gas such as an argon gas. The pressure of the atmospheric gas is set so as to have a pressure (about 100 kPa) exceeding atmospheric pressure, thereby efficiently ejecting the droplets 4 from the nozzle 1a.

The crucible 1 is composed of a material having a melting point higher than that of the material of the crystal. If the material of the crucible 1 reacts significantly to the molten solution of the material of the crystal, a large amount of the material of the crucible 1 is incorporated as impurities in the granular crystals. Thus, the material of the crucible 1 is preferably a material having low reactivity with the molten solution of the material of the crystal. For example, when the granular crystals 6 are composed of silicon, the crucible 1 is preferably composed of carbon, silicon carbide, silicon oxide, silicon nitride, aluminum oxide, or the like.

Induction heating, resistance heating, or the like is suitably employed as a method of heating the material of the crystal in the crucible 1 to the melting point.

The drop tube 2 attached to the nozzle 1a of the crucible 1 and extending downward is a vessel for cooling and solidifying the droplets 4 ejected from the nozzle 1a during dropping. The inside of the drop tube 2 is filled with a desired atmospheric gas and controlled to a desired pressure. A helium gas or an argon gas is preferred as the atmospheric gas. A helium gas or an argon gas is an inert gas and can prevent the contamination of the droplets 4 with impurities in the atmospheric gas.

Furthermore, preferably, a helium gas or an argon gas can suppress the formation of a reaction layer on the surface of the molten solution because low reactivity with the droplets 4, the reaction layer precluding the solidification and crystallization of the droplets 4. The pressure of the inert gas is controlled by adjusting the inlet flow rate of the inert gas and the outlet flow rate of the inert gas. That is, the atmospheric gas in the drop tube 2 is controlled by the predetermined gas.

The drop tube 2 is preferably composed of a material having a melting point higher than that of the material of the crystal. Alternatively, the drop tube 2 preferably has a cooling structure (not shown) for cooling thereof.

In the case of the drop tube 2 is composed of a material having a melting point higher than that of the material of the crystal, even when the droplets 4 are obliquely ejected to collide with the inner wall of the drop tube 2, the drop tube 2 is not heated to a temperature exceeding the melting point of the material constituting the drop tube 2; hence, the droplets 4 colliding with the drop tube 2 are not contaminated with the material of the drop tube 2 as impurities. For example, when the granular crystals 6 are composed of silicon, the drop tube 2 is preferably composed of a material having a melting point higher than that of silicon. Examples thereof include carbon, silicon carbide, silicon oxide, silicon nitride, and aluminum oxide.

In the case of the drop tube 2 is composed of a material having a melting point lower than that of the material of the crystal, when the droplets 4 are obliquely ejected outward to collide with the inner wall of the drop tube 2, the drop tube 2 may be heated to a temperature exceeding the melting point of the material constituting the drop tube 2; hence, the droplets 4 colliding with the drop tube 2 may be contaminated with the material of the drop tube 2 as impurities, which is not preferred. However, in the case where the drop tube 2 has a cooling structure for cooling thereof so as to prevent the drop tube 2 from being heated to the melting point or more due to the collision of the droplets 4, the drop tube 2 can be used without impurity contamination. For example, when the granular crystals 6 are composed of silicon, the drop tube 2 may be composed of a material, such as stainless steel or aluminum, having a melting point lower than that of silicon as long as the drop tube 2 is water-cooled with a double-pipe structure, a water-cooling jacket, or the like.

The longitudinally vibrating unit 3 has the function of applying longitudinal vibration (one-dimensional motion) for fragmenting the molten solution into droplets having a uniform grain size and then dropping the droplets. As a method of transmission of the longitudinal vibration, there are a method of driving the crucible 1 and a method of immersing the vibrating unit in the molten solution in the crucible 1. Examples of a vibrating method include piezoelectric methods, electromagnetic methods, and air methods. In FIG. 1, the longitudinal direction is indicated by V, for reference.

In the case of the method of vibrating the crucible 1, for example, a water-cooling shaft 7 is preferably disposed between the longitudinally vibrating unit 3 and the crucible 1. The water-cooling shaft 7 transmits the longitudinal vibration from the longitudinally vibrating unit 3 to the crucible 1 and prevents the transfer of heat for melting the material of the crystal. Specifically, the water-cooling shaft 7 includes a path through which cool water flows. Feeding cool water to the path from the outside prevents the heat transfer.

Preferably, the crucible 1 and the water-cooling shaft 7 are each composed of a high-stiffness material in order to efficiently transmit vibration. Specifically, when the granular crystals 6 are composed of silicon, each of the crucible 1 and the water-cooling shaft 7 is preferably composed of carbon, silicon carbide, silicon nitride, boron nitride, aluminum nitride, or aluminum oxide, or a combination of quartz and one of these materials.

The laterally vibrating unit 5 has the function of deflecting loci of the droplets 4 in such a manner that the uniform-sized droplets 4 fragmented with the longitudinally vibrating unit 3 are dropped so as not to collide with each other. In FIG. 1, the lateral (horizontal) direction is indicated by H, for reference.

In this embodiment, in order that the droplets 4 do not collide with each other, the lateral vibration is two-dimensional motion having no stop point on a lateral plane substantially perpendicular to the direction of dropping of the molten solution. The two-dimensional motion is motion in which the speed of the nozzle 1a is not zero at any given time on the lateral plane. Examples thereof include circular motion and elliptic motion.

Specifically, the three-dimensional motion of the nozzle 1a refers to compound vibration that vibrates in a plurality of directions. On the lateral plane, the three-dimensional motion means vibration satisfying the following formulae. That is, the three-dimensional motion includes the longitudinal motion V and the two-dimensional motion in the horizontal direction H in FIG. 1. The lateral plane is defined as a plane perpendicular to the longitudinal direction V.

$$\{ \begin{matrix}X = & {A}_{X} \cdot cos ( 2 π {f}_{X} t ) & ( {A}_{X} \neq 0 , {f}_{X} \neq 0 ) \\ Y = & {A}_{Y} \cdot sin ( 2 π {f}_{Y} t ) & ( {A}_{Y} \neq 0 , {f}_{Y} \neq 0 )\end{matrix} \qquad [ Formulae 1 ]$$

In the formulae, the X-direction is defined on the lateral plane. The Y-direction is defined as a direction orthogonal to the X-direction. A position after time t has coordinates (X, Y). In the formulae, A_{X} represents the amplitude in the X-direction. Ay represents the amplitude in the Y-direction. f_{X} represents a frequency applied in the X-direction. f_{Y} represents a frequency applied in the Y-direction. The ratio of A_{Y} to A_{X}, i.e., A_{Y}/A_{X}, is preferably about 0.2 to 5, more preferably 0.33 to 3, still more preferably 0.4 to 1.25.

That is, the two-dimensional motion on the lateral plane according to this embodiment functions as a two-dimensional harmonic oscillator that oscillates in the X-direction and the Y-direction.

The term “harmonic oscillator” refers to an oscillator that oscillates at a specific period independent of amplitude or a physical quantity corresponding to amplitude. In this embodiment, the harmonic oscillator serves as the two-dimensional harmonic oscillator on the lateral plane.

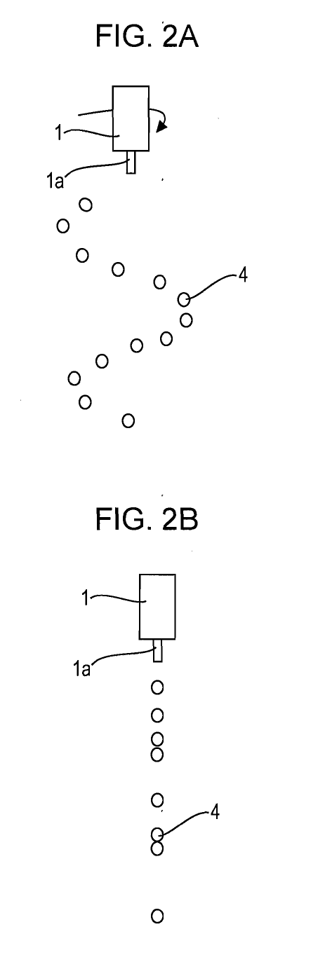

In the known art described in Japanese Unexamined Patent Application Publication No. 2002-292265, in the case of no two-dimensional motion in a lateral plane, i.e., in the case of longitudinal vibration alone, and in the case of the longitudinal vibration and one-dimensional harmonic oscillator that undergoes reciprocating motion in one direction on the lateral plane, the nozzle 1a is stopped in the lateral direction, or the lateral motion of the nozzle 1a has a stop point. Thus, the droplets 4 ejected from the crucible 1 with the longitudinally vibrating unit 3 collide easily, thereby increasing nonuniformity in the grain size of the granular crystals 6 (see FIG. 2B).

In contrast, the molten solution undergoes two-dimensional motion that does not have a stop point on the lateral plane, i.e., continuous motion on the lateral plane, with the longitudinal motion. Thus, eject positions of the droplets 4 from the crucible 1 are not easily superposed, thereby preventing the collision of the droplets 4 before the droplets 4 are solidified. Therefore, the granular crystals 6 having only a small nonuniformity in grain size can be reproducibly produced with high productivity (see FIG. 2A).

In the two-dimensional motion on the lateral plane, preferably, there is no superposed portion for a period of motion. In this case, the probability of the collision of the droplets 4 is further reduced.

Preferably, the two-dimensional motion on the lateral plane is circular motion on the lateral plane substantially orthogonal to the direction of dropping of the droplets 4, thereby surely deflecting the dropping loci of the droplets 4. Furthermore, a smaller diameter of the circular motion is preferred. Each of the droplets 4 is dropped obliquely downward so as to be dropped away from the center axis of the drop tube 2 with dropping resulting from a centrifugal force acting the nozzle 1a while describing a parabola. Thus, the dropping loci of many droplets 4 seem to describe helical loci, so that the diameter of a circle increases dropping height. As a result, the probability of the collision of the droplets 4 is further easily reduced.

The two-dimensional motion on the lateral plane is preferably circular motion. In this case, the circular motion can be easily controlled without changing the structure of the laterally vibrating unit 5 or the circuit wiring of a driving circuit of the laterally vibrating unit 5. For example, the radius of the locus of the circular motion can be controlled by adjusting the amplitude of vibration applied from the laterally vibrating unit 5 without changing the position or the structure of the nozzle 1a.

For example, the laterally vibrating unit 5 has a vibration-driving mechanism, such as a piezoelectric vibrating device, an electromagnetic vibrating device, or air vibrating device. The laterally vibrating unit 5 has a structure in which vibration (reciprocating motion) is converted into circular motion with a known cam or the like and in which the circular motion is transmitted to the crucible 1 through the water-cooling shaft 7. The laterally vibrating unit 5 controls the amplitude of vibration generated by the vibration-driving mechanism. In the case of the piezoelectric vibrating device or the electromagnetic vibrating device, the radius of the locus of the circular motion can be controlled by adjusting the input power of a driving signal. Furthermore, the speed of the circular motion can be controlled by adjusting the frequency of the driving signal. In the case of the air driving device, by adjusting an air pressure supplied to an air cylinder and an air supplying time, the amplitude and frequency of reciprocating motion (vibration) of a piston (connected to the water-cooling shaft 7) combined with the air cylinder can be controlled, thereby controlling the speed and the radius of the locus of the circular motion.

The embodiments of the present invention are not limited to the embodiments described above. Various changes may be made without departing from the scope of the invention.

For example, a plurality of nozzles 1a may be provided. The nozzle la is formed by forming a through hole in a circular plate composed of, for example, silicon carbide or silicon nitride. When a plurality of through holes are formed, the plurality of nozzles 1a can be made. In this case, a more large number of granular crystals 6 can be produced with a uniform grain size. The plurality of nozzles 1a are preferably formed so as to be located apart from each other in order to prevent the coalescence of the droplets 4. For example, preferably, the plurality of through holes are formed on a circle so as to be aligned at regular intervals, the center of the circle being the center of the plate in plan. Alternatively, by applying longitudinal vibration having a phase, the plurality of droplets 4 can be ejected at different timings because the ejection of the liquid column is different with time. In particular, this is effective in the case where the distance between the plurality of nozzles 1a is short.

For example, in the above-described embodiments, the granular crystals of silicon are exemplified. However, the present invention may be applied to a granular crystal used for a ball bearing and composed of stainless steel, a granular crystal used for jewelry goods and composed of gold, silver, platinum, or the like, and a granular crystal used for a metal powder or a ceramic powder for use in an abrasive grain or a sintering material. Furthermore, the present invention may be applied to the formation of glass particles having narrow particle size distribution.

The apparatus and the method for producing the granular crystal will be specifically described by means of an example.

### EXAMPLE

To a cylindrical crucible 1 having a length of 500 mm, a diameter of 100 mm, and composed of graphite, 800 g of silicon doped with B, as a p-type dopant, having a concentration of 1×10¹⁶ atom/cm³ was placed. The crucible 1 was heated with an electromagnetic induction heating device.

A pressure was applied to a molten solution in the crucible 1. The crucible 1 was longitudinally vibrated at a frequency of 10,000 Hz (10 kHz) and an amplitude of 1 μm with a longitudinally vibrating unit 3. Simultaneously, the crucible 1 was vibrated at an amplitude (A_{X}, A_{Y}) of 100 μm and at a frequency of 400 Hz in each of the X-direction and the Y-direction with a laterally vibrating unit 5 (in the formulae, amplitude A_{X}=A_{Y}=100 μm and f_{X}=f_{Y}=400 Hz). In this case, as two-dimensional motion on a lateral plane, circular motion that did not have a stop point was performed (the diameter of the locus of the circular motion: 100 μm). The molten solution was ejected from a nozzle 1a into the inside of a drop tube 2. Droplets 4 composed of silicon were dropped through the drop tube 2, cooled, and solidified to form granular crystals 6 of silicon. A water-cooling shaft 7 was provided between the crucible 1 and the longitudinally vibrating unit 3 and between the crucible 1 and the laterally vibrating unit 5.

### COMPARATIVE EXAMPLE

Granular crystals 6 of silicon were prepared as in EXAMPLE, except that the crucible 1 underwent the same longitudinal vibration alone, but no lateral vibration was applied.

In each of EXAMPLE and COMPARATIVE EXAMPLE, the average grain size, the standard deviation of the grain size, the average lifetime of a photoelectron generated by the photovoltaic converting effect of silicon, and the standard deviation of the lifetime were measured. Table 1 shows the results.

TABLE 1

| | | Standard | | Standard |
|---|---|---|---|---|
| | | deviation of | Average | deviation of |
| | Average grain | grain size | lifetime | lifetime |
| | size (μm) | (μm) | (μsec) | (μsec) |
| Example | 400 | 10 | 10 | 7 |
| Comparative | 800 | 200 | 0.5 | 4 |
| Example | | | | |

The results demonstrate that the granular silicon crystals obtained in EXAMPLE have a small nonuniformity in grain size, a small nonuniformity in quality, and high average quality, compared with the silicon granular crystals obtained in COMPARATIVE EXAMPLE. That is, according to the method of the present invention for producing the granular crystal, the small nonuniformity in grain size results in uniform crystal growth, thereby producing granular crystals having a small nonuniformity in the quality of the crystals.

FIG. 3A showing the grain size distribution of the granular crystals obtained in COMPARATIVE EXAMPLE demonstrates that another peak (satellite peak in the figure) assigned to large grains possibly grown by the collision of droplets is present other than the maximum peak (main peak in the figure). FIG. 3A shows the result of peak separation of the resulting peak.

In contrast, in FIG. 3B showing the grain size distribution of the granular crystals obtained in EXAMPLE, a main peak is observed. No satellite peak observed in COMPARATIVE EXAMPLE is present. That is, according to the present invention, the granular crystals having only a small nonuniformity in grain size can be reproducibly produced with high productivity.

What is claimed is:

1. A method for producing a granular crystal, comprising the steps of:
melting a crystal to be a molten solution;
ejecting a droplet of the molten solution from a nozzle with a three dimensional motion.

2. The method for producing a granular crystal according to claim 1,
wherein the three-dimensional motion includes longitudinal motion in the direction of gravity; and two-dimensional motion on a lateral plane perpendicular to the direction of the longitudinal motion.

3. The method for producing a granular crystal according to claim 2,
wherein the longitudinal motion is one-dimensional motion.

4. The method for producing a granular crystal according to claim 3,
wherein the one-dimensional motion has a frequency of 1 kHz to 50 kHz.

5. The method for producing a granular crystal according to claim 2,
wherein the two-dimensional motion has a frequency substantially equal to the natural frequency of the crucible.

6. The method for producing a granular crystal according to claim 2,
wherein the two-dimensional motion is circular motion.

7. The method for producing a granular crystal according to claim 2,
wherein the nozzle speed is not zero at any given time in the two-dimensional motion on the lateral plane.

8. The method for producing a granular crystal according to claim 7,
wherein the two-dimensional motion is harmonic motion.

9. The method for producing a granular crystal according to claim 2,
wherein any nozzle position with Cartesian coordinates (x, y) is set on the lateral plane, when the position after time t has coordinates (X, Y), the two-dimensional motion is expressed as the following formulae:
$$\{ \begin{matrix}X = & {A}_{X} \cdot cos ( 2 π {f}_{X} t ) & ( {A}_{X} \neq 0 , {f}_{X} \neq 0 ) \\ Y = & {A}_{Y} \cdot sin ( 2 π {f}_{Y} t ) & ( {A}_{Y} \neq 0 , {f}_{Y} \neq 0 )\end{matrix}$$

10. The method for producing a granular crystal according to claim 9,
wherein the frequency of X and the frequency of Y are 1/100 to ½ of the frequency of the longitudinal motion.

11. A method for producing a granular crystal, comprising:
a melting step of melting a material;
an ejecting step of ejecting a plurality of droplet of the molten material to disperse the plurality of droplet in a helical line; and
a solidifying step of solidifying the droplets during dropping.

12. The method for producing a granular crystal according to claim 11,
wherein the droplets make a distance in a longitudinal direction and on a lateral plane perpendicular to the longitudinal direction.

13. The method for producing a granular crystal according to claim 11,
wherein the droplets are dropped to be dropped away from the center axis of a drop tube.

14. The method for producing a granular crystal according to claim 11,
wherein the droplets are dropped to describe a parabola.

15. The method for producing a granular crystal according to claim 14,
wherein in the solidifying step, the droplets are cooled with an inert gas.

16. The method for producing a granular crystal according to claim 14,
wherein in the solidifying step, the droplets are cooled by being brought into contact with a cooling member.

17. The method for producing a granular crystal according to claim 16,
wherein the cooling member is the drop tube.

18. An apparatus for producing a granular crystal, comprising:
a crucible to contain a molten solution of a crystal;
an actuator to move at least one nozzle with three-dimensional motion; and
at least one nozzle to eject a droplet of the molten solution with a three dimensional motion.

19. The apparatus for producing a granular crystal according to claim 18,
wherein the actuator causes the nozzle to undergo the three-dimensional motion including longitudinal motion in the direction of gravity and two-dimensional motion on a lateral plane perpendicular to the longitudinal direction.

20. The apparatus for producing a granular crystal according to claim 18,
wherein the at least one nozzle comprises a plurality of nozzles.

21. The apparatus for producing a granular crystal according to claim 19, further comprising:
a cooling shaft disposed between the crucible and the actuator.
